(19) United States
(12) Patent Application Publication
(10) Pub. No.: US 2006/0249769 A1
(43) Pub. Date: Nov. 9, 2006

(54) Semiconductor memory device and method for fabricating a semiconductor memory device

(76) Inventors: Florian Eder, Erlangen (DE); Marcus Halik, Erlangen (DE); Hagen Klauk, Stuttgart (DE); Gunter Schmid, Hemhofen (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/361,648

(22) Filed: Feb. 24, 2006

(30) Foreign Application Priority Data
Feb. 24, 2005 (DE) 10 2005 009 511.9

(51) Int. Cl. H01L 29/94

(52) U.S. Cl. 257/296

(57) ABSTRACT

A semiconductor memory device and method for fabricating a semiconductor memory device is disclosed. In one embodiment, the semiconductor memory device using at least one ferroelectric layer which has at least one electrically non-conductive polymer and ferroelectric nanoparticles distributed in the polymer. In another embodiment, the present invention provides a method for fabricating a semiconductor memory device using at least one ferroelectric layer. It is thus possible to fabricate a semiconductor memory device using at least one ferroelectric layer on inexpensive and, if appropriate, flexible substrates.

### CROSS-REFERENCE TO RELATED APPLICATION

This Utility Patent Application claims priority to German Patent Application No. DE 10 2005 009 511.9, filed on Feb. 24, 2005, which is incorporated herein by reference.

### FIELD OF THE INVENTION

The invention relates to a semiconductor memory device and a method for fabricating a semiconductor memory device using ferroelectric layers.

### BACKGROUND

Semiconductor memory devices can be subdivided in principle into volatile and non-volatile semiconductor memory devices.

The most important and commercially most successful representative of volatile semiconductor memory devices is the DRAM (“dynamic random access memory”), in which the items of information are stored within the individual memory cells in the form of electrical charges on capacitors. On account of unavoidable leakage currents within the memory cells and between adjacent memory cells, the charge stored on the DRAM capacitors has to be refreshed regularly (usually several times per second); after the operating voltage has been switched off, the items of information stored in the DRAM are generally lost.

This disadvantage is avoided in the case of non-volatile semiconductor memory devices. One example of non-volatile semiconductor memory devices is constituted by ferroelectric semiconductor memory devices, in which the phenomenon of electrical polarization of ferroelectric layers is utilized for storing information. Ferroelectric materials have a crystal structure which, when the temperature falls below a specific temperature (the Curie temperature), for energetic reasons undergoes transition from the completely symmetrical cubic lattice state to a non-symmetrical tetragonal lattice state. In this tetragonal lattice, the centroids of the positive and negative charges within the unit cell do not coincide, and so an electric dipole arises in each unit cell. Within ferroelectric crystallites, the dipoles of adjacent unit cells influence one another, so that regions of uniform dipole orientation (so-called domains) form spontaneously. If a layer of a ferroelectric material is arranged between two electrically conductive electrodes, then the layer can be polarized in one direction by applying a positive electrical voltage and in the other direction by applying a negative voltage. The orientation of the electric dipole moments that is thus established is maintained by virtue of the internal polarization of the ferroelectric material even after the electrical voltage has been switched off.

In order to read out the stored information, the orientation of the internal polarization has to be ascertained. For this purpose, an electrical voltage above the coercitive voltage is applied to the layer, so that the layer is polarized in one direction or the other. If the polarity of the applied voltage is opposite to the direction of the internal polarization, then the polarization of the layer is reversed, and the transfer of the electric charges within the layer leads to a compensating charge flow in the external electric circuit, which is detected by means of a suitable amplifier circuit. If the polarity of the applied voltage matches the direction of the internal polarization, then a reversal of the polarization of the layer does not occur, nor does a compensating charge flow in the electric circuit. The read-out of the stored information thus essentially consists in a changeover of the layer and the evaluation of the electric charges transferred in the process. After the read-out, the layer can be programmed with the original information again.

The materials that are generally used for ferroelectric semiconductor memory devices are perovskites or layered perovskites, to be precise usually PbTiO₃, PbZrₓTi₁₋ₓO₃ (PZT) or SrBi₂Ta₂O₃ (SBT). Below the Curie temperature, these materials have a tetragonal lattice structure with a unit cell extended elastically along one of the three crystallographic axes. Along the extended axis there exist two stable positions which the four-fold positively charged central ion (Ti, Zr or Ta) can occupy. Since neither of these two positions coincides with the center of mass of the unit cell, the occupation of both positions is associated with the formation of an electric dipole moment.

In order to realize ferroelectric semiconductor memory devices, the ferroelectric layer is divided into individual memory cells. In each memory cell, the ferroelectric layer is contact-connected with a bottom electrode and a top electrode in order to enable the stored information to be electrically written, read and erased. In order to realize ferroelectric semiconductor memory devices having storage capacities of megabits or gigabits, the memory cells are arranged in two-dimensional arrays. Arranging the memory cells in two-dimensional arrays permits the realization of a large number (m*n) of cells with a small number of word lines (m) and bit lines (n), but for reliably reading out the stored information requires the use of a switching semiconductor component, preferably of a field effect transistor, in each of the cells.

The fabrication of conventional ferroelectric memory cells on the basis of ferroelectric perovskite layers is known from the literature (see e.g. S. R. Gilbert, S. Hunter, D. Ritchey, C. Chi, D. V. Taylor, J. Amano, S. Aggarwal, T. S. Moise, T. Sakoda, S. R. Summerfelt, K. K. Singh, C. Kazemi, D. Carl, and B. Bierman, “Preparation of Pb(Zr,Ti)03 thin films by metalorganic chemical vapor deposition for low voltage ferroelectric memory,” Journal of Applied Physics, Vol. 93, p. 1713 (2003)).

Ferroelectric semiconductor memory devices are currently produced exclusively on silicon platforms, that is to say that the semiconductor memory devices are fabricated exclusively on silicon substrates (silicon wafer) and exclusively using transistors based on silicon as semiconductor.

Transistor concepts are currently being developed which manage without the use of silicon wafers and which enable the fabrication of integrated circuits on inexpensive glass substrates and even on flexible polymer films. In principle, it is possible to implement a processing of high-quality electrically insulating polymer layers based on polyvinyl phenol at temperatures of at most 200° C. and the use thereof as gate dielectric for the fabrication of field effect transistors based on organic semiconductors on arbitrary substrates (including glass, plastic, paper and flexible polymer film) (see e.g.:

H. Klauk, M. Halik, U. Zschieschang, F. Eder, G. Schmid, and C. Dehm, “Pentacene Organic Transistors and Ring Oscillators on Glass and on Flexible Polymeric Substrates,” Applied Physics Letters, Vol. 82, p. 4175 (2003);

M. Halik, H. Klauk, U. Zschieschang, G. Schmid, W. Radlik, and W. Weber, “Polymer Gate Dielectrics and Conducting Polymer Contacts for High-Performance Organic Thin Film Transistors,” Advanced Materials, Vol. 14, p. 1717 (2002); and

H. Klauk, M. Halik, U. Zschieschang, G. Schmid, W. Radlik, and W. Weber, “High Mobility Polymer Gate Dielectric Pentacene Thin Film Transistors,” Journal of Applied Physics, Vol. 92, p. 5259 (2002)), all incorporated herein by reference.

The deposition and crystallization of ferroelectric layers based on perovskite materials PbTiO₃, PZT and SBT as used for fabricating ferroelectric semiconductor memory devices are normally effected, however, at relatively high temperatures (at least about 600° C.) that are far greater than the melting point of polymer films (about 150 to 350° C.) and greater than the melting point of glass (about 550° C.). Therefore, it is normally not possible to use PbTiO₃, PZT and SBT on these inexpensive and, if appropriate, flexible substrates.

For these and other reasons, there is a need for the present invention.

### SUMMARY

The present invention provides a semiconductor memory device and a method for fabricating a semiconductor memory device. In one embodiment, the semiconductor memory device is configured to have at least one ferroelectric layer which has at least one electrically non-conductive polymer and ferroelectric nanoparticles distributed in the polymer.

In another embodiment, the present invention provides a method for fabricating a semiconductor memory device using at least one ferroelectric layer. It is thus possible to fabricate a semiconductor memory device using at least one ferroelectric layer on inexpensive and, if appropriate, flexible substrates.

### BRIEF DESCRIPTION OF THE DRAWING

FIG. 1 illustrates a schematic sectional view of a ferroelectric memory cell in a programmable semiconductor memory device.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The present invention provides a semiconductor memory device using at least one ferroelectric layer on inexpensive substrates.

In one embodiment, the invention provides for a semiconductor memory device using at least one ferroelectric layer which has at least one ferroelectric layer made of at least one electrically non-conductive polymer and ferroelectric nanoparticles distributed in the polymer. The use of ferroelectric particles makes it possible to realize a ferroelectric layer together with a polymer which has the same properties as a layer which consists entirely of a ferroelectric material.

One preferred embodiment provides for providing a semiconductor memory device having at least one ferroelectric layer using organic semiconductors. In such a semiconductor memory device, switching components are advantageously realized using organic semiconductors.

In one advantageous embodiment of such a semiconductor memory device, the substrate at least partly has glass, paper, plastic and/or polymer films or comprises these materials.

It is advantageous to use ferroelectric nanoparticles, for example based on the materials PbTiO₃ and PZT, which are produced by means of a sol gel method or from the gas phase (for example by cathode ray sputtering, evaporation or laser ablation) (see K. S. Seol, S. Tomita, K. Takeuchi, T. Miyagawa, T. Katagiri, and Y. Ohki, “Gas-phase production of monodisperse lead zirconate titanate nanoparticies,” Applied Physics Letters, Vol. 81, p. 1893 (2002), and B. Jiang, J. L. Peng, L. A. Bursill, and W. L. Zhong, “Size effects on ferroelectricity of ultrafine particles of PbTiO₃,” Journal of Applied Physics, Vol. 87, p. 3462 (2000)). Those nanoparticles which have been produced by means of a sol gel method and also those nanoparticles which have been fabricated by means of a gas phase process, for example by cathode ray sputtering, evaporation or laser ablation, are suitable for the processing of ferroelectric layers according to the invention. The nanoparticles preferably comprise perovskites, in particular PbTiO₃, PbZr_{X}Ti_{1-X}O₃, and/or SrBi₂Ta₂O₃.

The ferroelectric nanoparticles may have an average size of about 5 nm to about 200 nm. Their size is preferably about 10 to 50 nm.

Polymers which are not conjugated and are readily soluble in organic solvents are advantageously used as polymer for fabricating the ferroelectric layer. In one preferred embodiment, polyvinyl phenol is used as a polymer having the abovementioned properties. Ethanol and propylene glycol monomethyl ether acetate (PGMEA) are advantageously used as solvent.

In order to produce the at least one ferroelectric layer, the ferroelectric nanoparticles are preferably dispersed in the polymer. The ferroelectric nanoparticles are advantageously dispersible in the polymer dissolved in an organic solvent.

A dispersion produced in this way can advantageously be spun onto a substrate.

In one embodiment, the bottom electrodes and, if appropriate, the transistors are implemented on the substrate.

The solvent can advantageously be removed from the layer in a drying process at a temperature of about 100° C.

It is advantageous that the polymer is crosslinkable thermally at a temperature of at most about 200° C. In a further preferred embodiment, the polymer is crosslinkable optically by irradiation with short-wave light.

Electrodes are advantageously implemented on at least one ferroelectric layer.

In one embodiment, the semiconductor memory device is realized from individual memory cells arranged in two-dimensional arrays with the features described above.

In this case, each memory cell advantageously in each case has a switching semiconductor component, in particular a field effect transistor, made of organic semiconductors.

In one variant, the semiconductor memory device is formed in programmable fashion.

The present invention also provides a method for fabricating semiconductor memory devices using at least one ferroelectric layer. According to one embodiment of the invention, the at least one ferroelectric layer for such a semiconductor memory device is fabricated by the dispersion of ferroelectric nanoparticles in at least one polymer.

In one embodiment of the method, the processing of the ferroelectric layers is effected at temperatures of below about 200° C. This affords the advantage over conventional methods for fabricating ferroelectric semiconductor memory devices that the semiconductor memory devices according to the invention can be fabricated on cost-effective and, if appropriate, flexible substrates.

In one preferred embodiment of the method, a substrate is used which at least partly has glass, paper, plastic and/or polymer films or comprises these materials.

In the case of the method, the ferroelectric nanoparticles are advantageously produced by means of a sol gel method or from the gas phase, in particular by cathode ray sputtering, evaporation or laser ablation.

In one embodiment, the polymer is dissolved in an organic solvent and the ferroelectric nanoparticles are dispersed in the dissolved polymer.

The dispersion is then advantageously spun onto a substrate. In one preferred embodiment, electrodes and, if appropriate, transistors are implemented prior to the application of a ferroelectric layer on the substrate.

The solvent is removed after the application advantageously by means of a drying process at a temperature of about 100° C.

In one variant, the polymer is crosslinked thermally at a temperature of at most 200° C. or optically.

Electrodes are advantageously implemented on at least one ferroelectric layer.

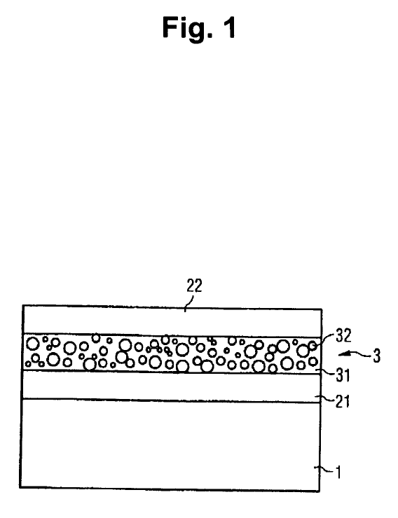

FIG. 1 illustrates a schematic representation of a ferroelectric memory cell that is part of a programmable semiconductor memory device which is not illustrated completely here for clarity.

A programmable semiconductor memory device using at least one ferroelectric layer is generally constructed from a multiplicity of memory cells arranged in two-dimensional arrays.

FIG. 1 illustrates a schematic diagram of an individual ferroelectric memory cell. A first electrode 21 is implemented on a substrate 1, the electrode being covered by a ferroelectric layer 3. A second electrode 22 is in turn implemented on the ferroelectric layer. By means of a voltage applied to the two electrodes 21 and 22, the ferroelectric layer 3 can be polarized in one direction or the other depending on the sign of the voltage. The orientation of the electric dipole moments that is established in this way is maintained on account of the internal polarization of the ferroelectric material even after the electrical voltage has been switched off.

In contrast to the embodiment illustrated here, in a conventional ferroelectric memory cell the ferroelectric layer 3 is constructed entirely from a ferroelectric material. In this case, materials that are generally used for conventional ferroelectric semiconductor memory devices are perovskites or layered perovskites, to be precise usually PbTiO₃, PbZrₓTi₁₋ₓO₃ (PZT) or SrBi₂Ta₂O₃ (SBT). Owing to the relatively high temperatures necessary for the deposition and crystallization of ferroelectric layers based on the perovskite materials PbTiO₃, PZT and SBT as used for the fabrication, silicon is often used in this case as material for the substrate 1.

FIG. 1 illustrates an embodiment of a ferroelectric memory cell in an embodiment of the semiconductor memory device. The ferroelectric layer 3 comprises ferroelectric nanoparticles 32 dispersed in a polymer 31. By virtue of the nanoparticles 32 dispersed in the polymer, the layer 3 has ferroelectric properties, similarly to a layer consisting exclusively of a ferroelectric material. Here, too, the nanoparticles 32 preferably comprise perovskites, in particular PbTiO₃, PbZrₓTi₁₋ₓO₃, and/or SrBi₂Ta₂O₃. The functioning of a ferroelectric memory cell realized in this way is exactly the same as in the case of a conventional ferroelectric memory cell described above.

An embodiment of a method according to the invention for fabricating a programmable semiconductor memory device having a multiplicity of individual ferroelectric memory cells has the advantage that it proceeds at temperatures of up to at most 200° C. As a result, it is possible to use as material for the substrate 1 glass, paper, plastic or polymer films, that is to say materials which are inexpensive and, if appropriate, flexible.

In one embodiment of the method according to the invention, the beam of a pulsed Nd: yttrium-aluminum-garnet (YAG) laser is focused through a window onto the surface of a PZT-ceramic cylinder installed in a vacuum chamber, thus resulting in the ablation of PZT particles from the surface of the cylinder. The nanoparticles produced in this way are caught by an oxygen stream and transported into a vacuum furnace flanged onto the vacuum chamber. In said furnace, the nanoparticles are crystallized at a temperature of about 900° C. and an oxygen partial pressure of about 400 Pa to form virtually spherical perovskites which have the desired ferroelectric properties. The residence time of the nanoparticles in the furnace is regulated by the oxygen flow to about 0.05 second. The ferroelectric nanoparticles having a size of about 20 to 50 nm are collected on a suitable substrate and then dispersed in the previously dissolved polymer (20 parts of polyvinyl phenol and 1 part of poly(melamine-co-formaldehyde) in propylene glycol monomethyl ether acetate). In order to produce the ferroelectric layer, the dispersion comprising the dissolved polymer and the ferroelectric nanoparticles is spun onto a flexible polyethylene naphthalate substrate on which the bottom (for example metallic) electrode has previously been deposited and patterned by means of photolithography and wet-chemical etching. The spun-on ferroelectric layer is dried at a temperature of 100° C. (the propylene glycol monomethyl ether acetate solvent is driven out in the process) and then crosslinked thermally at a temperature of 200° C. Finally, the top (for example once again metallic) electrode is produced on the ferroelectric layer.

Embodiments of the invention are not restricted to the exemplary embodiments specified above. Rather, a number of variants are conceivable which make use of the device according to the invention and the method according to the invention also in the case of embodiments of fundamentally different configuration.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor memory device comprising:
at least one ferroelectric layer, characterized in that the at least one ferroelectric layer having at least one electrically non-conductive polymer with ferroelectric nanoparticles distributed in the polymer.

2. The semiconductor memory device according to claim 1, comprising wherein switching components are realized with organic semiconductors.

3. The semiconductor memory device according to claim 1, comprising a substrate which at least partly has glass, paper, plastic and/or polymer films or comprises these materials.

4. The semiconductor memory device according to claim 1, comprising wherein the ferroelectric nanoparticles are produced by means of a sol gel method.

5. The semiconductor memory device according to claim 1, comprising wherein the ferroelectric nanoparticles are produced from a gas phase, by cathode ray sputtering, evaporation or laser ablation.

6. The semiconductor memory device according to claim 1, comprising wherein the ferroelectric nanoparticles have a size of between 5 nm and 200 nm.

7. The semiconductor memory device according to claim 1, comprising wherein the ferroelectric nanoparticles comprise perovskites, in particular PbTiO₃, PbZrₓTi₁₋ₓO₃, and/or SrBi₂Ta₂O₃.

8. A semiconductor memory device comprising:
at least one ferroelectric layer, comprising wherein the at least one ferroelectric layer having at least one electrically non-conductive polymer with ferroelectric nanoparticles distributed in the polymer, and wherein the electrically non-conductive polymer is a conjugated polymer that is readily soluble in organic solvents.

9. The semiconductor memory device according to claim 8, comprising wherein the electrically non-conductive polymer is polyvinyl phenol.

10. The semiconductor memory device according to claim 9, comprising wherein the solvent is ethanol or propylene glycol monomethyl ether acetate (PGMEA).

11. The semiconductor memory device according to claim 9, comprising wherein the ferroelectric nanoparticles are dispersible in the dissolved polymer.

12. The semiconductor memory device according to claim 11, comprising wherein the dispersion can be applied to a substrate by spinning-on.

13. The semiconductor memory device according to claim 12, comprising wherein electrodes and transistors are implemented on the substrate.

14. The semiconductor memory device according to claim 13, comprising wherein the solvent can be removed by means of a drying process at a temperature of about 100° C.

15. The semiconductor memory device according to claim 14, comprising wherein the polymer is crosslinkable thermally at a temperature of at most 200° C. or optically.

16. The semiconductor memory device according to claim 1, characterized in that electrodes are implemented on at least one ferroelectric layer.

17. The semiconductor memory device according to claim 1, comprising wherein the semiconductor memory device is realized from individual memory cells arranged in two-dimensional arrays.

18. The semiconductor memory device according to claim 17, comprising wherein the individual memory cells each have a switching semiconductor component, including a field effect transistor, made of organic semiconductors.

19. The semiconductor memory device according to claim 1, comprising wherein it is formed in programmable fashion.

20. A method for fabricating a semiconductor memory device comprising:
using at least one ferroelectric layer;
fabricating in that the at least one ferroelectric layer by means of a distribution, including dispersion, of ferroelectric nanoparticles in at least one polymer.

21. The method according to claim 20, comprising wherein processing of the at least one ferroelectric layer is effected at temperatures of below 200° C.

22. The method according to claim 20, comprising wherein glass, paper, plastic and/or polymer films are at least partly used as material for the substrate.

23. The method according to claim 20, comprising wherein the ferroelectric nanoparticles are produced by means of a sol gel method or from the gas phase, in particular by cathode ray sputtering, evaporation or laser ablation.

24. The method according to claim 20, comprising wherein the polymer is dissolved in an organic solvent.

25. The method according to claim 24, comprising wherein the ferroelectric nanoparticles are dispersed in the dissolved polymer.

26. The method according to claim 25, comprising wherein the dispersion is applied to a substrate by spinning-on.

27. The method according to claim 26, comprising wherein electrodes and transistors are implemented on the substrate prior to the application of the at least one ferroelectric layer.

28. The method according to claim 27, comprising wherein the solvent is removed by means of a drying process at a temperature of about 100° C.

29. The method according to claim 28, comprising wherein the polymer is crosslinked thermally at a temperature of at most 200° C. or optically.

30. The method according to claim 29, comprising wherein electrodes are implemented on at least one ferroelectric layer.

31. A semiconductor memory device comprising:
at least one ferroelectric layer, characterized in that the at least one ferroelectric layer having at least one electrically non-conductive polymer with ferroelectric nanoparticles distributed in the polymer.
